(19) United States
(12) Patent Application Publication
(10) Pub. No.: US 2024/0180040 A1
(43) Pub. Date: May 30, 2024

(54) ACOUSTIC TRANSISTOR

(71) Applicant: Portland State University, Portland, OR (US)

(72) Inventor: Rajendra Solanki, Portland, OR (US)

(73) Assignee: Portland State University, Portland, OR (US)

(21) Appl. No.: 18/521,473

(22) Filed: Nov. 28, 2023

Related U.S. Application Data
(60) Provisional application No. 63/428,684, filed on Nov. 29, 2022.

(51) Int. Cl. H10N 30/00; H10N 30/80; H10N 30/853; H10N 39/00

(52) U.S. Cl. CPC H10N 30/1071; H10N 30/802; H10N 30/853; H10N 39/00

(57) ABSTRACT

A MOSFET is turned On and Off by applying an acoustic signal to a material having a piezoelectric effect to generate a charge creating a conducting path at the silicon/gate oxide interface. In an acoustic transistor, instead of the gate voltage, the accumulation of the charge under the oxide region is created by a piezoelectric material stimulated by an acoustic (sound) wave from an acoustic generator. A piezoelectric thin film, such as Aluminum Nitride or HfSiO, can be deposited near the transistor to stimulate the signal and another piezo film also on top of the silicon oxide/aluminum gate. The acoustic waves from a signal generator on the silicon surface bounce within the substrate and stimulate the piezo film on top of the gate oxide. This results in electric charge across the oxide film, induced by the piezo film on top of the gate and turns on and off the transistor.

### CROSS REFERENCE TO RELATED APPLICATION

This application claims priority from U.S. Provisional Application No. 63/428,684, filed Nov. 29, 2022, which application is incorporated herein by reference in its entirety.

### FIELD

The present disclosure relates to transistors and, particularly, to Metal oxide semiconductor field effect transistors (MOSFETs).

### BACKGROUND

MOSFETs are utilized for a wide range of applications in modern electronic devices. One of the most common applications is for computing, where logic devices can be turned on and off to produce the digital 1 or 0. There are two types of MOSFETs, n-channel and p-channel where the carriers can be either electrons or holes, respectively.

In conventional n-type MOSFETs (shown in FIG. 1 at 100), a source 110 is connected to a ground signal (not shown), an input signal is connected to a gate (V_{G}) 120, and there is a small voltage applied between the source and a drain 130 (V_{DS}). When the gate 120 receives an input signal (positive voltage for n-type devices), an oxide layer 140 acts as a capacitor, so the input voltage charges up this capacitor and induces a positive charge at the oxide/silicon interface (wherein the silicon is shown at 150). This charge attracts free electrons (minority carriers) in the p-type doped channel region between the source and drain. These electrons accumulate just below the gate oxide 140. If the signal voltage is large enough (i.e., above the threshold voltage), the sufficient density of electrons accumulate below the oxide to create an electrically conducting path for a current to pass from the source to drain (drawn by the source to drain voltage), thereby turning the transistor on and producing a digital 1. If the gate voltage falls below the threshold value, then the conducting path disappears, and the flow of the current stops, turning the transistor off (i.e., a digital 0). The bottom body connection 160 can be biased to adjust the threshold value of the transistor.

In an Integrated Circuit (IC), there can be billions of transistors. A timing signal is coupled to the transistors to synchronize turning the transistors on and off. Typically, the timing signal is coupled to the gate 120 of each transistor. Coupling the timing signal to billions of transistors results in a significant power usage for the IC.

### BRIEF DESCRIPTION OF THE DRAWINGS

FIG. 1 is a prior art MOSFET.

FIG. 2 is a first embodiment of an acoustic MOSFET, wherein a material having piezoelectric effect is used as gate material and an acoustic signal generator is used to activate the transistor.

FIGS. 3A-3C include an example prototype with screen shots of output currents used as a result of the acoustic signal generator activating the transistor.

FIG. 4 includes an additional embodiment of an acoustic MOSFET.

FIG. 5 includes yet another embodiment of the acoustic MOSFET.

FIG. 6 is another embodiment wherein a single acoustic generator controls multiple transistors within an IC.

FIG. 7 is a flowchart according to one embodiment.

### DETAILED DESCRIPTION

Embodiments described herein allow for a MOSFET to be turned On and Off by applying an acoustic signal and utilizing a piezoelectric film to generate the charge to create a conducting path at the silicon/gate oxide interface. One advantage of the acoustic transistor is that a supplied gate voltage is not needed (or is greatly reduced) to switch the transistor on/off. Considering that a modern logic chip consists of billions of such transistors, the absence or reduction of the gate voltage eliminates a significant amount of energy consumption leading to low power, energy efficient electronic devices. In an acoustic transistor, instead of the gate voltage, the accumulation of the charge under the oxide region is created by a piezoelectric material stimulated by an acoustic (sound) wave from an acoustic generator.

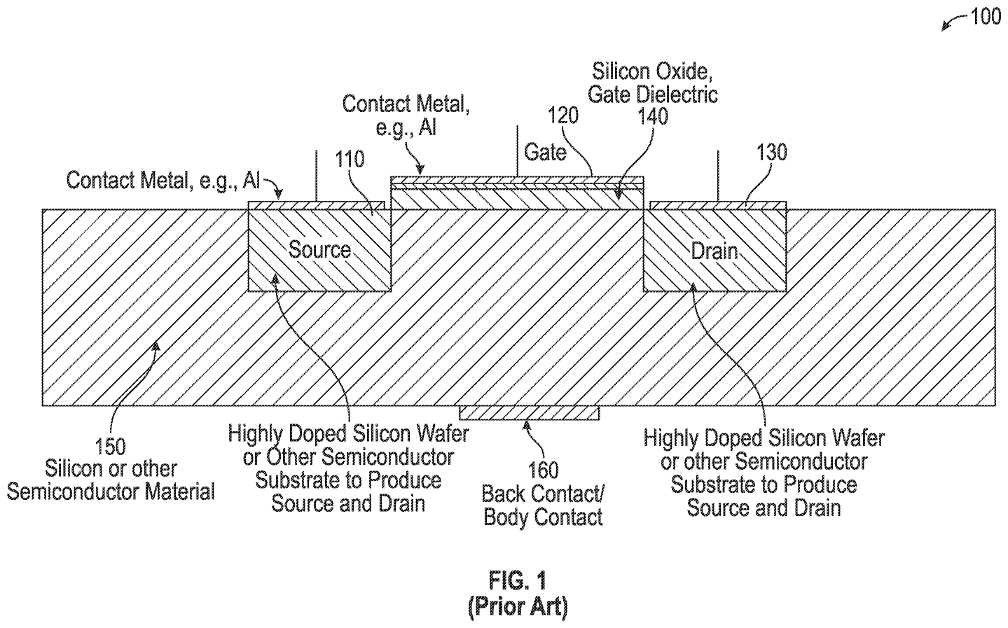

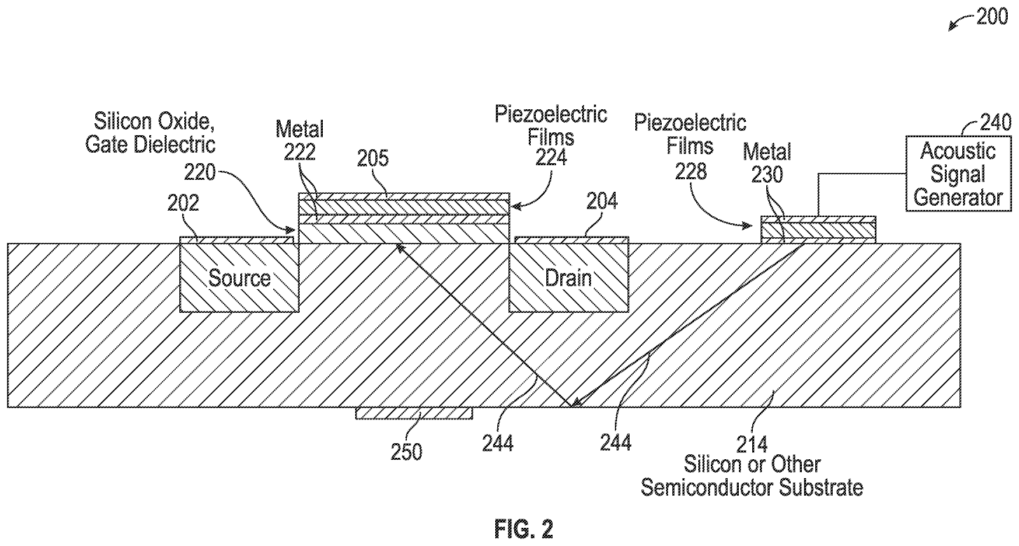

One embodiment of an acoustic transistor 200 is shown in FIG. 1. The acoustic transistor 200 includes a source region 202, a drain region 204, and a gate region 205 positioned between the source region 202 and drain region 204. The gate region 205 is formed from a silicon oxide gate dielectric 220 deposited on a substrate 214. The gate region 205 further includes two metal layers 222 and a piezoelectric film 224, which is positioned between the metal layers 222. One of the metal layers 222 is deposited on the silicon oxide gate dielectric 220. The other of the metal layers 222 can be used for coupling the gate 205 to copper signal lines (not shown) in an IC. A piezoelectric thin film 228, such as Aluminum Nitride, can be positioned adjacent to the transistor 200 and between metal layers 230. One of the metal layers 230 can be deposited on the substrate 214 and the other metal layer 230 can be used for coupling to an acoustic signal generator 240. The acoustic signal generator 240 can stimulate a signal in the piezoelectric film 228 and generate acoustic waves (shown by arrows 244) that bounce off a bottom of the substrate 214 and stimulate the piezo film 224. This results in electric charge across the silicon oxide gate dielectric 220, induced by the piezoelectric film 224 on top of the gate 205, which turns ON (activates) and OFF (deactivates) the transistor 200. Although the acoustic signal generator 240 is shown coupled to a top of a substrate 214, it can also be coupled to other portions of the substrate, such as at a bottom. Additionally, a threshold voltage on the gate 205 can be adjusted through applying a back voltage 216 to control an amount of induced voltage needed to be generated by the acoustic wave 244. As described herein, a piezoelectric film is a material that exhibits a piezoelectric effect or otherwise has piezoelectric properties. Example materials include Aluminum Nitride, Gallium Nitride (GaN), Hafnium Silicate (HfSiO₄), etc. However, newer materials are being developed can be used. Consequently, a wide variety materials exhibiting the piezoelectric effect can be used with the embodiments described herein.

The embodiments described herein address the limitations faced by modern ICs. First, with billions of transistors on an IC, the described embodiments reduce and/or eliminate the gate signal of an array of transistors, thereby reducing the power consumption, which also reduces the thermal budget. Second, the described approach eliminates the need for a synchronization signal to turn on and off the transistors, which further reduces the required electrical power consumption of ICs.

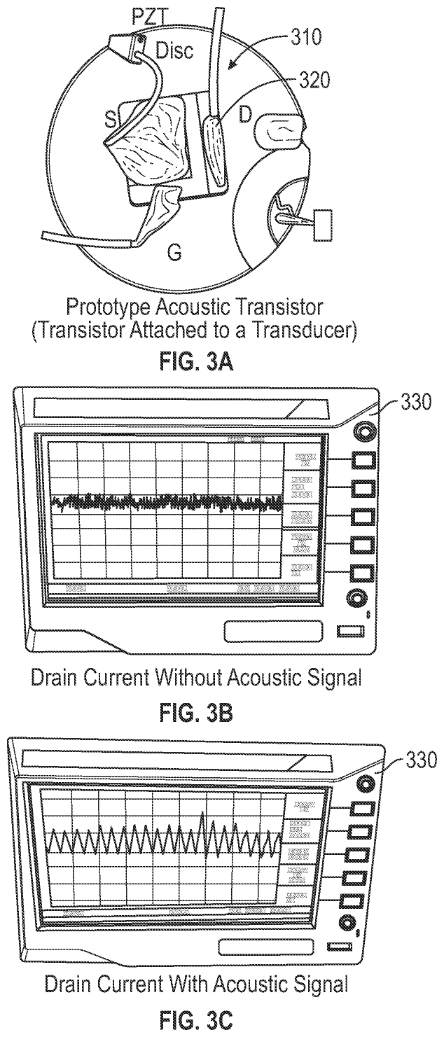

FIGS. 3A through 3C represent a proof of concept of this approach and was demonstrated using a commercial GaN transistor and an acoustical modulator. A transistor 310 was glued to a transducer (FIG. 3a) and powered with a signal generator. In this case GaN substrate is the piezo component of the transistor that is activated. A current from a drain 320 current was monitored on an oscilloscope 330. Without the acoustic signal, the drain current just showed noise (FIG. 3b), whereas with the acoustic signal, a pulsed drain current output of the transistor was detected (FIG. 3c).

The embodiments described herein can be applied to FinFETs and Gate-all-around FETs (GAAFET). The progress in semiconductor device technology has been driven by downscaling of the device size. This trend resulted in a reduction of the thickness of the gate oxide, i.e., thickness of silicon oxide gate dielectric. However, reduction of the gate oxide has led to increased leakage current between the gate and the silicon substrate. To address this issue, a new gate dielectric was developed that has a high dielectric constant (or high-k) so that a thicker layer of this material can be used in place of silicon oxide to reduce/eliminate the leakage current, while maintaining a high capacitance of the gate.

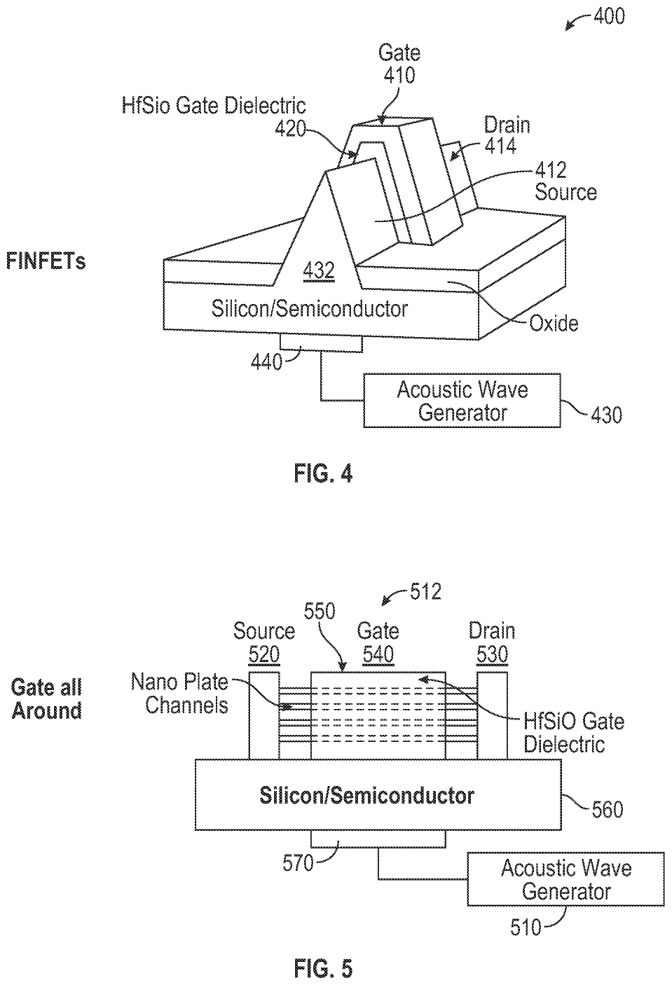

FIG. 4 is an example of using an acoustic wave generator in conjunction with a FinFET. A gate 410 is shown between a source 412 and a drain 414. The gate 410 is partially constructed using a HfSiO material 420 having piezoelectric properties. The hafnium silicate has the piezoelectric coefficient d₃₁ of about −11.5 pm/V, which is more than five times larger than that of Aluminum Nitride. An acoustic wave generator 430 can be coupled to a semiconductor layer 432 using a connector 440 that includes a material having a piezoelectric property. Any of the previously described materials can be used. In some cases, the HfSiO gate dielectric films are thin and may not be sufficient to generate the required charges to turn on the gate. In such a case, back (or body) contacts can be used to selectively supplement the piezo generated voltage to lower the threshold voltages of only the transistors that we wish to turn on. Since the acoustic wave generator can be integrated within an IC either at its top or bottom, this approach can be used to choose which transistors are turned on.

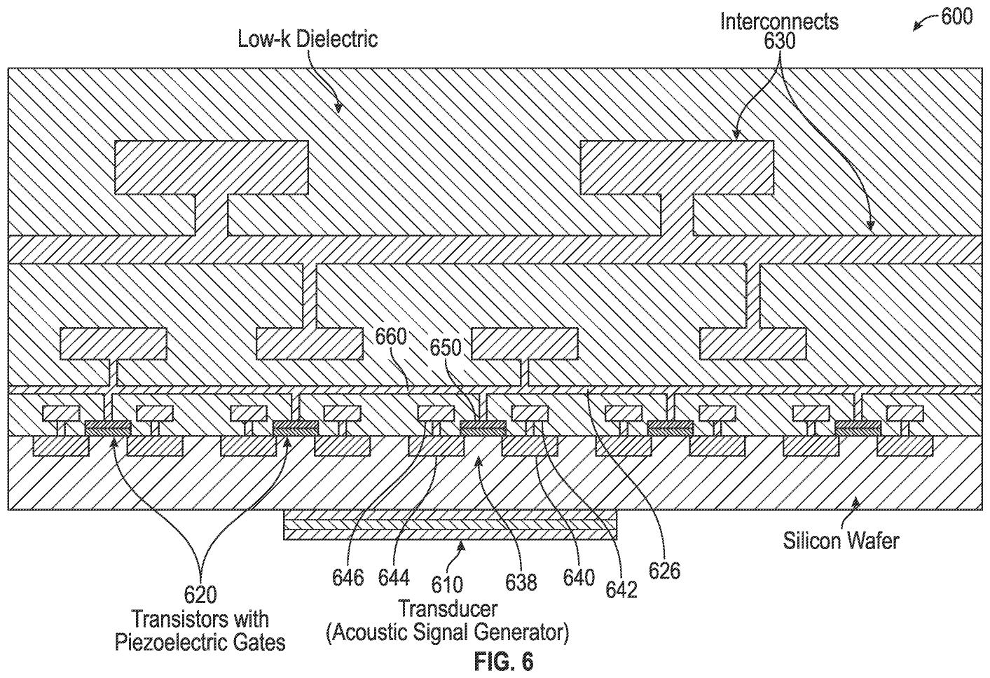

FIG. 5 shows another embodiment wherein an acoustic wave generator 510 is used in conjunction with a GAA transistor 512. Thus the acoustic technic is not limited to planar transistors, but is also applicable to the more advanced 3-dimensional transistors. In this case, a source 520, drain 530 and gate 540 support multiple parallel transistors 550 mounted on a shared substrate 560. The gate 540 includes HfSiO as the material having the piezoelectric properties. The acoustic wave generator 510 is coupled to the substrate 560 using a connector 570 that also includes piezoelectric material. In this case, the acoustic wave generator 510 can turn on and off all of the transistors 550 in parallel. Although the transistors 550 are shown as 4 parallel transistors, other numbers of transistors can be controlled in parallel using the acoustic wave generator.

The acoustic transistor embodiments described herein can also be used in other applications, such as dynamic random access memory (DRAM), where each cell consists of a capacitor and a transistor. The dielectric of these capacitors is generally a ceramic oxide (e.g., BaTiO₃ and SrTiO₃) that have a large charge storage capacity. These oxides are also piezoelectric material and the capacitors can be charged using acoustic waves. The purpose of the transistor is to work as a valve, i.e., when closed keeps the capacitor charged and discharges the capacitors when open. Therefore, by using HfSiO dielectric for the transistors, these two goals can be achieved. First, all the ceramic capacitors can be charged with the acoustic generator and, second, at the same time, by applying back bias to the selected transistors to open them, their respective capacitors are discharged. So, one can address an array of these cells with a single action and consuming no current. Such a memory or storage device will consume very little energy.

FIG. 6 is an example of an array of acoustic transistors 600. A single acoustic transducer 610, which receives a signal from an acoustic signal generator (also called an acoustic wave generator)(not shown) can be used to control multiple transistors 620 (2, 3, 4 . . . etc.) with gates having a piezoelectric film associated therewith. The layout of interconnects on ICs is such that each interconnect layer is orthogonal to each other. One layer of interconnects 626 can run parallel to the 2-D image of FIG. 6 and a next layer 630 can be perpendicular thereto. There are narrow connections to sources and drains, which can then be connected to the orthogonal interconnects (shown as wider rectangles). One of the transistors 638 is described for purposes of completeness, but the other transistors 620 are identical. The transistor 638 includes a drain 640, with a drain interconnect 642, and a source 644 with a source interconnect 646. A gate 650 is positioned between the drain 640 and source 644. The gate 650 includes a metal layer and a layer of material having piezoelectric properties, as described herein. The gates of the transistors are coupled together by interconnect 660 and the transistors can be turned on/off together using the single acoustic transducer 610. More specifically, the acoustic signal from the transducer induces charge in the piezoelectric film of the gates, which is sufficient to turn on the transistors. If the acoustic signal turns off, then the transistors correspondingly turn off due to the lack of charge being induced. Thus, using a single transducer 610, thousands or millions of gates can be turned on or off simultaneously, without injecting additional charge on the gate interconnect 660 through traditional means. The interconnect 660 can maintain a voltage near a threshold level so that the transducer 610 can push the gates over the threshold to turn the transistors on.

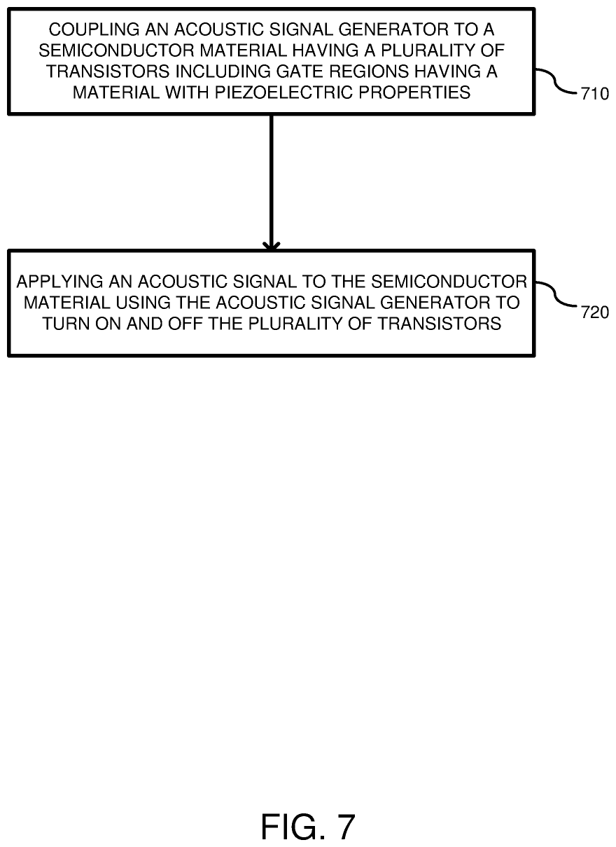

FIG. 7 is a flowchart according to one embodiment. In process block 710, an acoustic signal generator is coupled to a semiconductor material having a plurality of transistors associated therewith. Each of the plurality of transistors include a gate region having a material with piezoelectric properties. The acoustic signal generator can be any hardware device used to produce acoustic signals, which are sound waves in the MHz to GHz frequency range. The acoustic signals can be in the form of sine waves, square waves, triangle waves and other waveforms commonly used in the high-frequency range. For example, in FIG. 6, an acoustic signal generator can be coupled to a transducer at 610, which includes a material having piezoelectric properties, to produce acoustic signals within the semiconductor material. A plurality of transistors 638 can include gate regions having material with a piezoelectric effect. In process block 720, an acoustic signal from an acoustic signal generator is applied and turns on and off the transistors in unison. Thus, the transistors can be turned on simultaneously all at once in the presence of the acoustic signal and then can be turned off when the acoustic signal is shut off.

In view of the many possible embodiments to which the principles of the disclosed invention may be applied, it should be recognized that the illustrated embodiments are only preferred examples of the invention and should not be taken as limiting the scope of the invention. Rather, the scope of the invention is defined by the following claims. We therefore claim as our invention all that comes within the scope of these claims.

We claim:

1. A system, comprising:
an array of transistors being positioned on a semiconductor material with each transistor including a source region, a drain region, and a gate region positioned between the source and drain regions, with the gate region including a layer of material having piezoelectric properties; and
an acoustic signal generator coupled to the semiconductor material for activating and deactivating the array of transistors through interaction between an acoustic signal produced by the acoustic signal generator and the layer of material having the piezoelectric properties.

2. The system of claim 1, wherein the piezoelectric material is an HfSiO dielectric layer between a doped polysilicon or a metal gate of the gate region and the semiconductor material.

3. The system of claim 1, wherein the acoustic signal generator is coupled to a same side of the semiconductor material as the gate region.

4. The system of claim 1, wherein the acoustic signal generator is coupled to an opposite side of the semiconductor material as the gate region.

5. The system of claim 1, wherein the array of transistors are Metal oxide semiconductor field effect transistors (MOSFETs).

6. The system of claim 5, wherein the MOSFETs are Gate-All-Around type transistors.

7. The system of claim 5, wherein the MOSFETS are Fin field-effect type transistors.

8. A method, comprising:
coupling an acoustic signal generator to a semiconductor material having a plurality of transistors, wherein each of the plurality of transistors includes a source region, a drain region and a gate region positioned between the source and drain regions, wherein the gate region includes a material having piezoelectric properties;
applying an acoustic signal to the semiconductor material using the acoustic signal generator to turn on and turn off the plurality of transistors using the interaction between the acoustic signal and the material having the piezoelectric properties.

9. The method of claim 8, wherein the piezoelectric film is an HfSiO dielectric layer between a metal gate of the gate region and the semiconductor material.

10. The method of claim 8, wherein the acoustic signal generator is coupled to a same side of the semiconductor material as the gate region.

11. The method of claim 8, wherein the acoustic signal generator is coupled to an opposite side of the semiconductor material as the gate region.

12. The method of claim 8, wherein each transistor is a Metal oxide semiconductor field effect transistors (MOSFETs).

13. The method of claim 12, wherein the MOSFETs are Gate-All-Around type transistors.

14. The method of claim 8, wherein the MOSFETS are Fin field-effect type transistors.

15. A Metal oxide semiconductor field effect transistor (MOSFET), comprising:
a semiconductor substrate;
a source region;
a drain region;
a gate region between the source and drain regions, the gate region including a first material exhibiting a piezoelectric effect; and
an input having a second material exhibiting a piezoelectric effect, the input being coupled to the semiconductor substrate for receiving an acoustic signal.

16. The MOSFET of claim 15, wherein the first material is an HfSiO dielectric layer between a polysilicon/metal gate of the gate region and the semiconductor material.

17. The MOSFET of claim 15, wherein the input for receiving the acoustic signal is coupled to a same side of the semiconductor substrate as the gate region.

18. The MOSFET of claim 15, wherein the input for receiving the acoustic signal is coupled to an opposite side of the semiconductor material as the gate region.

19. The MOSFET of claim 15, wherein the MOSFET is a Gate-All-Around type transistor.

20. The MOSFET of claim 15, wherein the MOSFET is a fin field-effect type transistor.
